(19) United States
(12) Patent Application Publication
(10) Pub. No.: US 2015/0075849 A1
(43) Pub. Date: Mar. 19, 2015

(54) SEMICONDUCTOR DEVICE AND LEAD FRAME WITH INTERPOSER

(71) Applicants: Jia Lin Yap, Klang (MY); Yin Kheng Au, Petaling Jaya (MY)

(72) Inventors: Jia Lin Yap, Klang (MY); Yin Kheng Au, Petaling Jaya (MY)

(21) Appl. No.: 14/029,766

(22) Filed: Sep. 17, 2013

(51) Int. Cl. H01L 23/495; H01L 23/00

(52) U.S. Cl. CPC H01L 23/495; H01L 24/43
USPC 174/257; 257/676; 438/123; 174/261; 174/258

(57) ABSTRACT

A semiconductor device includes a lead frame having a flag and leads surrounding the flag. The flag includes a first die attach area and an interposer area. An insulated layer with at least one conductive trace is formed on the interposer area.

### BACKGROUND OF THE INVENTION

The present invention relates to integrated circuit (IC) device assembly and, more particularly, to lead frames for semiconductor packages.

A System-In-a-Package (SiP) is a package incorporating multiple readily available dies into a single package. The multiple dies are internally connected with bond wires. A SiP device performs all or most of the functions of an electronic system, and is widely used in electric devices.

FIG. 1A shows a schematic top plan view of a conventional SiP device 100 including a lead frame 102 having a flag 104 and a plurality of leads 106 surrounding the flag 104. The flag 104 has a first die attach area 108 and a second die attach area 110. A first die 112 is attached on the first die attach area 108 and electrically connected to the leads 106 with a set of first bond wires 114. A second die 116 is attached on the second die attach area 110 and electrically connected to the first die 112 with a set of second bond wires 118. In addition, a third die 120 is attached on a top surface of the first die 112 with an epoxy material and electrically connected to the first die 112 with a set of third bond wires 122. The SiP device 100 may be, for example, a sensor package, where the first die 112 is a micro-control unit (MCU), the second die 116 is a gravity sensor, and the third die 120 is a pressure sensor.

FIG. 1B is a cross-sectional view of the conventional SiP device 100 from the line 1-1 of FIG. 1A. When assembling the device 100, the first and second dies 112 and 116 are first attached to the flag 104 of the lead frame 102. Then the third die 120 is attached on the top surface of the first die 112 with an epoxy material, followed by a wire bonding process to electrically connect the first die 112 to the leads 106 with the set of first bond wires 114, and the second die 116 to the first die 112 with the set of second bond wires 118. Then a pre-molding process is performed to encapsulate the lead frame 102, first die 112, second die 116, first bond wires 114 and second bond wires 118 with a mold compound 124. Since the third die 120 is a pressure sensor die, an opening 126 must be left over the third die 120 after the pre-molding process so that a gel 128 may be dispensed over the third die 120, and to allow for electrically connecting the third die 120 to the first die 112 with the third bond wires 122.

The opening 126 is created with a film molding process in which a film is placed on top of the third die 120 to prevent the molding compound 124 from flowing into the area of the opening 126. However, this procedure has a very narrow process tolerance since a minor offset of the film molding process may damage the first and second bond wires 114 and 118. In addition, the epoxy material used to attach the third die 120 to the top surface of the first die 112 can cause epoxy resin bleed onto the bond pads (not shown) of the first die 112, result in wire bondability issues.

One solution to avoid the aforementioned problems is to attach the third die 120 directly on the flag like the first and second dies 112 and 116. However, this can lead to wire routing issues amongst the multiple dies and leads. Further, the space on the flag 104 is limited.

It is therefore desirable to find a solution to resolve the wire routing and bondability issues of the convention SiP.

### BRIEF DESCRIPTION OF THE DRAWINGS

The invention, together with objects and advantages thereof, may best be understood by reference to the following description of preferred embodiments together with the accompanying drawings in which:

FIG. 1A is a top plan view of a conventional SiP semiconductor device;

FIG. 1B is a cross-sectional side view of a the SiP device of FIG. 1A along line 1-1 of FIG. 1A;

FIG. 2 is a top plan view of a SiP device in accordance with an embodiment of the present invention;

FIGS. 3A-3E are top plan views of a various interposer designs in accordance with embodiments of the present invention;

FIG. 4 is a top plan view of a SiP semiconductor device in accordance with another embodiment of the present invention;

FIG. 5 is a top plan view of a SiP semiconductor device in accordance with a further embodiment of the present invention;

FIGS. 6A-6E are a series of diagrams illustrating the steps in forming an interposer on a flag of a lead frame in accordance with an embodiment of the present invention; and

FIGS. 7A-7C are a series of diagrams illustrating the steps in forming an interposer on a flag of a lead frame in accordance with another embodiment of the present invention.

### DETAILED DESCRIPTION OF PREFERRED EMBODIMENTS

The detailed description set forth below in connection with the appended drawings is intended as a description of presently preferred embodiments of the invention, and is not intended to represent the only forms in which the present invention may be practised. It is to be understood that the same or equivalent functions may be accomplished by different embodiments that are intended to be encompassed within the spirit and scope of the invention. In the drawings, like numerals are used to indicate like elements throughout. Furthermore, terms “comprises,” “comprising,” or any other variation thereof, are intended to cover a non-exclusive inclusion, such that module, circuit, device components, structures and method steps that comprises a list of elements or steps does not include only those elements but may include other elements or steps not expressly listed or inherent to such module, circuit, device components or steps. An element or step proceeded by “comprises . . . a” does not, without more constraints, preclude the existence of additional identical elements or steps that comprises the element or step.

In one embodiment, the present invention provides a semiconductor device including a lead frame having a flag and a plurality of leads surrounding the flag. The flag includes a first die attach area and an interposer area, and an insulated layer plated with at least one conductive trace formed on the interposer area.

In another embodiment, the present invention provides a lead frame including a flag having a first die attach area and an interposer area, a plurality of leads surrounding the flag, and an insulated layer plated with at least one conductive trace formed on the interposer area.

In a further embodiment, the present invention provides a method for assembling a semiconductor device. The method includes providing a lead frame having a flag and a plurality of leads surrounding the flag. The flag includes a first die attach area and an interposer area; The method includes forming an insulated layer on the interposer area and plating at least one conductive trace on the insulated layer.

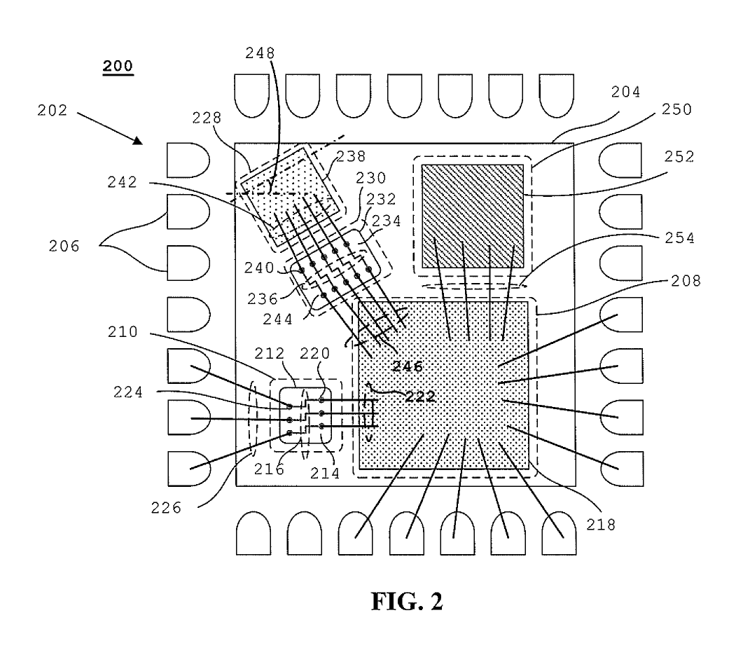

Referring now to FIG. 2, a top plan view of a semiconductor device 200 in accordance with an embodiment of the present invention is shown. The semiconductor device 200 includes a lead frame 202 having a flag 204 and a plurality of leads 206 surrounding the flag 204. The flag 204 includes a first die attach area 208 and a first interposer area 210. A first interposer 212 is formed on the first interposer area 210. The first interposer 212 includes a first insulated layer 214 plated with a plurality of first conductive traces 216. In a preferred embodiment, the first insulated layer 214 is glass, ceramic or a polymer based material, which is low-cost. In another preferred embodiment, the first insulated layer 214 is formed with a screen print or photo mask process, which is known in the art and easily implemented. A thickness of the first interposer 212 may vary depending on the package requirements, including package dimensions and reliability requirements, therefore the first interposer 212 can be used even in very thin packages. In a preferred embodiment, the first conductive traces 216 are copper traces formed with a copper plating process. In a further preferred embodiment, a silver layer is plated on an upper surface of each of the first conductive traces 216.

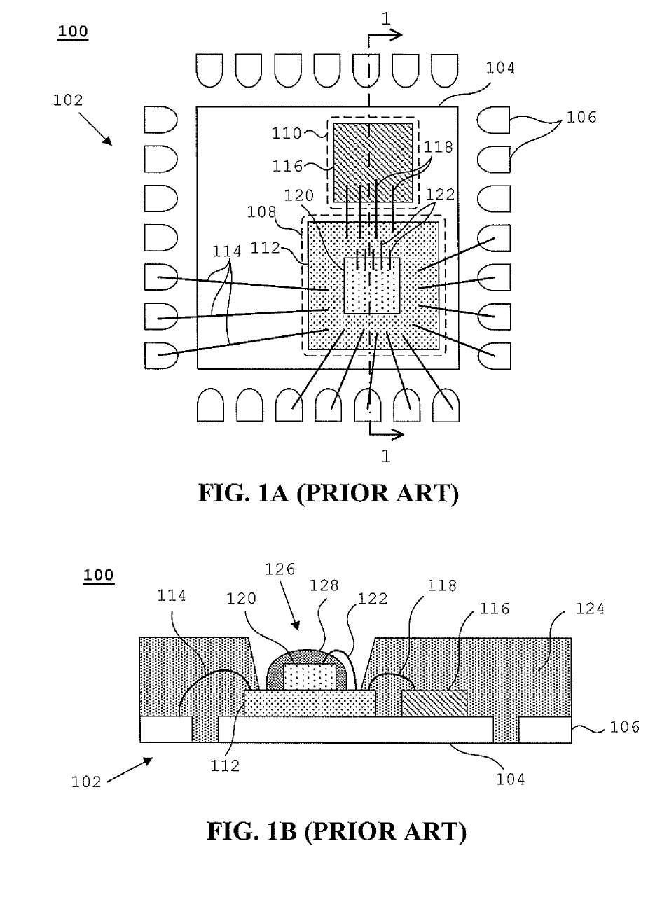

A first die 218 is attached on the first die attach area 208, and electrically connected to a first end 220 of each of the plurality of first conductive traces 216 with a set of first bond wires 222. Second ends 224 of the first conductive traces 216 are electrically connected to the leads 206 of the lead frame 202 with a set of second bond wires 226. For example, the first die 218 may be an MCU die. By using the first interposer 212, both of the sets of first and second bond wires 222 and 226 have shorter lengths than the set of first bond wires 114 in the conventional device 100 shown in FIG. 1. Therefore, wire bondability issues due to long bond wires can be avoided.

In a preferred embodiment, the flag 204 includes a second die attach area 228 and a second interposer area 230. A second interposer 232 is formed on the second interposer area 230. Similar to the first interposer 212, the second interposer 232 includes a second insulated layer 234 plated with a plurality of second conductive traces 236. In a preferred embodiment, the second insulated layer 234 is glass, ceramic or a polymer based material. In another preferred embodiment, the second conductive traces 236 are copper traces formed with a copper plating process. In a further preferred embodiment, a silver layer is plated on an upper surface of each of the second conductive traces 236.

A second die 238 is attached on the second die attach area 228, and is electrically connected to a first end 240 of each of the plurality of second conductive traces 236 with a set of third bond wires 242. Second ends 244 of the second conductive traces 236 are electrically connected to the first (MCU) die 218 with a set of fourth bond wires 246. For example, the second die 238 may be a pressure sensor die. The first die 218 and the second die 238 are not stacked so epoxy resin bleed onto bond pads of the first die 112 that resulted in the conventional device 100 due to die stacking is avoided, while as shown in FIG. 2, by using the second interposer 232, the second die 238 placed on the flag can be rotated at an angle 248 with respect to the first die 246 so that routing between the first die 218 and the second die 238 is flexible. Further, as with the first interposer 212, the second interposer 232 allows shorter bond wires to be used for the connections between the first and second dies 218 and 238.

In a preferred embodiment, the flag 204 includes a third die attach area 250 having a third die 252 attached thereon. The third die 252 is electrically connected to the first die 218 with a set of fifth bond wires 254. The third die 252 may be, for example, an acceleration sensor die.

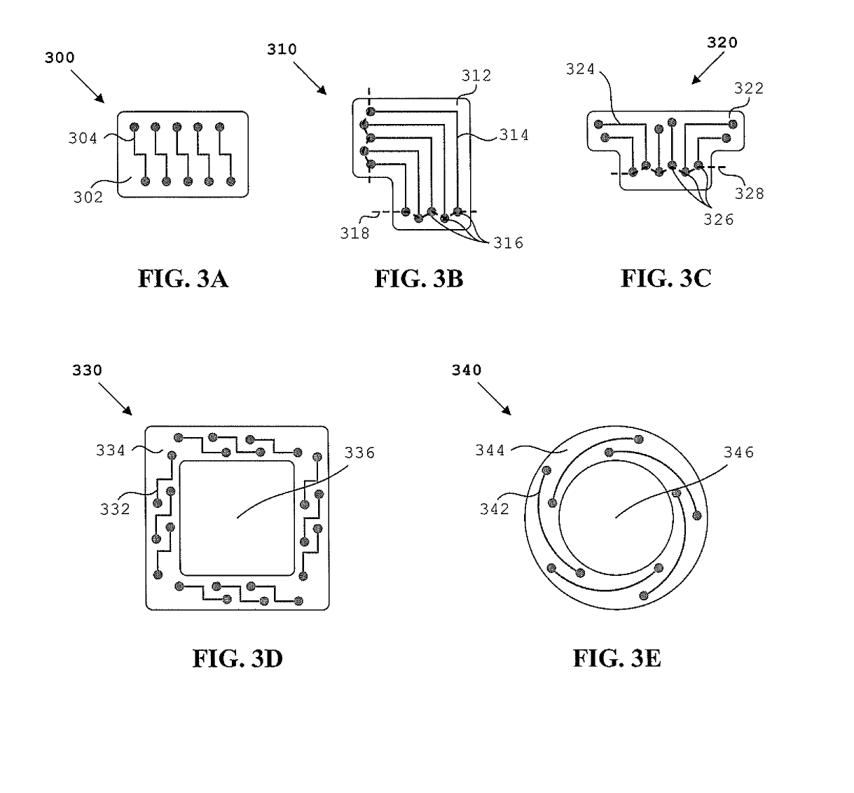

FIGS. 3A-3E are schematic top plan views of a plurality designs of an interposer in accordance with embodiments of the present invention.

FIG. 3A shows an interposer 300 having a rectangular shaped insulated layer 302. A plurality of conductive traces 304 are arranged in parallel on the insulated layer 302 for carrying electrical signals from one side of the insulated layer 302 to an opposite side.

FIG. 3B shows an L-shaped interposer 310. A plurality of conductive traces 314, also L-shaped, are arranged on an insulated layer 312. In one embodiment, each of the conductive traces 314 has at least one contact element 316 for wire bonding. The contact elements 316 are arranged in a zigzag row as indicated by dotted line 318. The zigzag or offset arrangement of the contact elements allows the conductive traces 314 to be placed very close to each other while avoiding wire shorting problems.

FIG. 3C shows an interposer 320 having a T-shaped insulated layer 322. A plurality of conductive traces 324 are arranged on the insulated layer 322, as shown. Similar to the interposer 310 of FIG. 3B, in one embodiment, each of the conductive traces 324 has at least one contact element 326 for wire bonding, where the contact elements 326 are offset from one another or arranged in a zigzag row as indicated by dotted line 328, which allows the conductive traces 324 to be placed very close to each other while avoiding wire shorting problems.

FIG. 3D shows an interposer 330 having a rectangular shaped insulated layer 332 with a rectangular cut-out 336. A plurality of Z-shaped conductive traces 334 are arranged along the sides of the insulated layer 332.

FIG. 3E shows an interposer 340 having a ring-shaped insulated layer 342. A plurality of conductive traces 344 are arranged around a center 346 of the insulated layer 342.

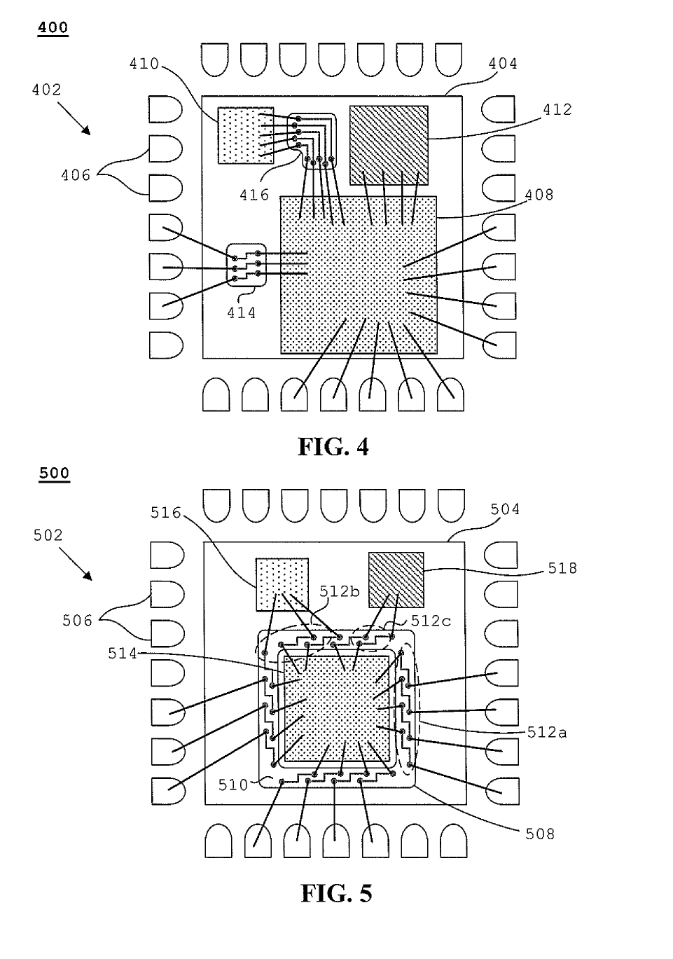

Referring to FIG. 4, a schematic top plan view of a semiconductor device 400 in accordance with an embodiment of the present invention is shown. Similar to the semiconductor device 200 shown in FIG. 2, the semiconductor device 400 includes a lead frame 402 having a flag 404 and a plurality of leads 406 surrounding the flag 404. A first die 408, a second die 410 and a third die 412 are attached on a surface of the flag 404. The flag 404 also has a first interposer 414 for helping to electrically connect the first die 408 to the leads 406, and a second interposer 416 for helping to electrically connect the second die 410 to the first die 408. The first and second interposers 414 and 416 are formed on the surface of the flag 404. However, different from the second interposer 232 in FIG. 2, the second interposer 416 in FIG. 4 is L-shaped, like the interposer 310 shown in FIG. 3B.

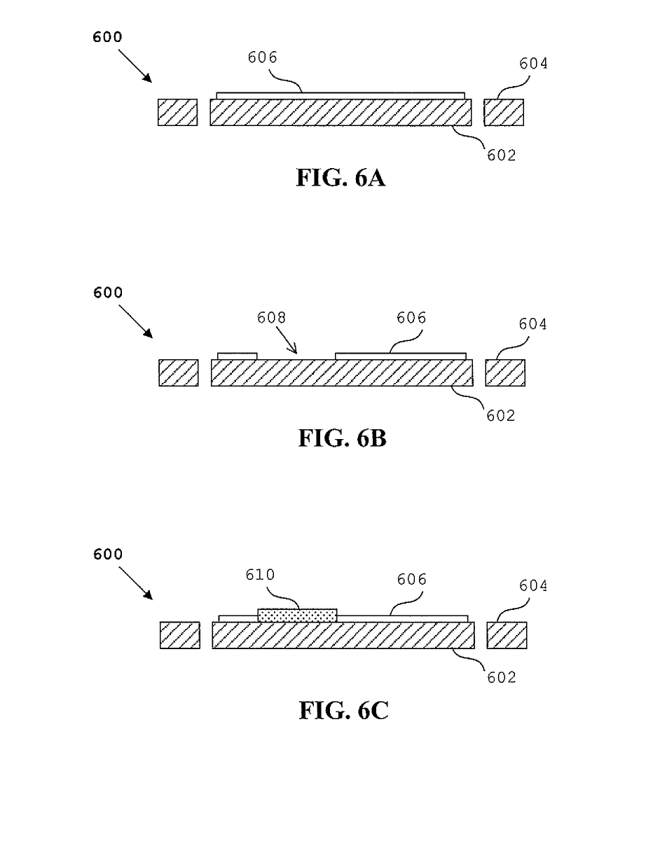

Referring to FIG. 5, a schematic top plan view of a semiconductor device 500 in accordance with another embodiment of the present invention is shown. The semiconductor device 500 includes a lead frame 502 having a flag 504 and a plurality of leads 506 surrounding the flag 504. An interposer 508 is formed on the flag 504. Like the interposer 330 shown in FIG. 3D, the interposer 508 has a rectangular, ring-shaped insulated layer 510, and a plurality of conductive traces including a set of first conductive traces 512a, a set of second conductive traces 512b, and a set of third conductive traces 512c arranged around the sides of the insulated layer 510. A first die 514 is located within the ring-shaped insulated layer 510 and is attached to the flag 504. The set of first conductive traces 512a are used to electrically connect the first die 514 to the leads 506. A second die 516 and a third die 518 are attached on the flag 504, but outside the insulated layer 510. The set of second conductive traces 512b electrically connect the second die 516 to the first die 514, and the set of third conductive traces 512c electrically connect the third die 518 to the first die 514. In one embodiment, the first die 514 is a MCU die, the second die 516 is a pressure sensor die, and the third die 518 is a gravity or acceleration sensor die.

As discussed above, the interposer may comprise a variety of form or shapes, as well the conductive traces also can have various patterns. Therefore, wire routing between the dies in the package can be arranged in any form of designated routing as needed.

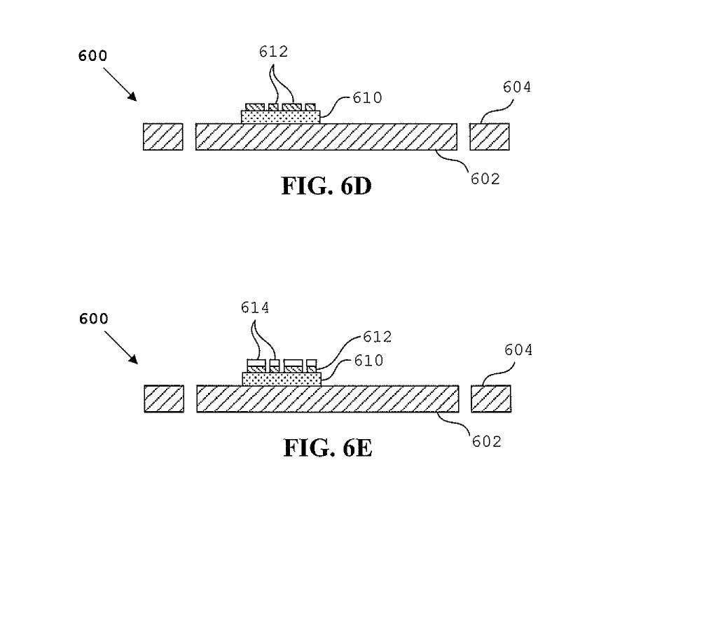

FIGS. 6A-6E are a series of diagrams illustrating the steps in forming an interposer on a flag of a lead frame in accordance with an embodiment of the present invention. Beginning with FIG. 6A, a lead frame 600 having a flag 602 and a plurality of leads 604 surrounding the flag 602 is provided. A photoresist layer 606 is applied on a top surface of the flag 602.

In the next step illustrated in FIG. 6B, an opening 608 is formed in the photoresist layer 606 by etching. The opening 608 is sized and shaped based on the size and shape of the interposer being formed.

In the next step illustrated in FIG. 6C, an insulated layer 610 is formed within the opening 608, and is bonded directly on the top surface of the flag 602. The insulated layer 610 may be formed of glass, ceramic, a polymer based material, or the like.

In the next step illustrated in FIG. 6D, the photoresist-layer 606 is removed, and a plurality of conductive traces 612 is formed on a top surface of the insulated layer 610. In one embodiment, the conductive traces 612 are deposited on the insulted layer 610 by plating or sputtering. The conductive traces 612 may be formed of copper, gold, or other conductive metals as are typically used in semiconductor device assembly.

In the next step illustrated in FIG. 6E, a finishing layer 614 is plated on the conductive traces 612. In a preferred embodiment, the finishing layer 614 is silver, nickel, palladium, or gold, or any other materials that can be used for wire bonding.

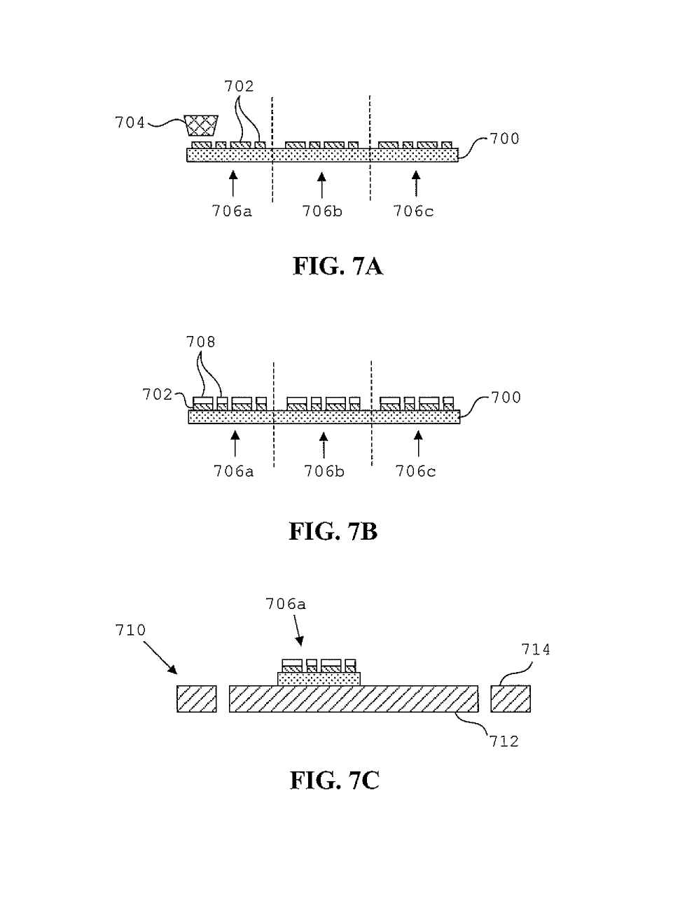

FIGS. 7A-7C are a series of diagrams illustrating the steps in forming an interposer on a flag of a lead frame in accordance with another embodiment of the present invention. Starting with FIG. 7A, an insulated layer 700 is provided. In a preferred embodiment, the insulated layer 700 is formed of self-adhesive polymeric based materials. Conductive traces 702 are printed on a top surface of the insulated layer 700 with a print head 704 to form an interposer 706a. In one embodiment, the conductive traces 702 are formed of copper. In another embodiment, the conductive traces of multiple interposers 706a-706c are formed on a large insulated layer at the same time.

In the next step illustrated in FIG. 7B, the conductive traces 702 are plated with a finishing layer 708. The finishing layer 708 may be silver, nickel, palladium, or gold, as are known in the art.

In the next step illustrated in FIG. 7C, a lead frame 710 having a flag 712 and a plurality of leads 714 surrounding the flag 712 is provided, and the interposer 706a is attached on the flag 712. In a preferred embodiment, the interposer 706a is singulated from the plurality of interposers 706a-706c before being attached to the flag 712. In a preferred embodiment, the interposer 706a is attached to the flag 712 with an adhesive material. In another preferred embodiment, the insulated layer 700 is a self-adhesive polymeric based material that can be directly attached on the flag 712.

Thus, the present invention provides a lead frame having an interposer and the use of the lead frame and interposer to assemble a multi-chip package. The interposer allows the dies to have various orientations on the lead frame yet still be connected by way of bond wires to that extend to/from the interposer(s). The interposer also allows for shorter length bond wires so issues such as wire sag are avoided.

The description of the preferred embodiments of the present invention has been presented for purposes of illustration and description, but is not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiment disclosed, but covers modifications within the spirit and scope of the present invention as defined by the appended claims.

1. A semiconductor device, comprising:
a lead frame having a flag and a plurality of leads surrounding the flag, wherein the flag includes a first die attach area and an interposer area; and
an insulated layer plated with at least one conductive trace formed on the interposer area.

2. The semiconductor device of claim 1, further comprising:
a first die attached on the first die attach area;
a first bond wire electrically connecting the first die to a first end of the conductive trace; and
a second bond wire electrically connecting a second end of the conductive trace to a lead of the lead frame.

3. The semiconductor device of claim 1, further comprising:
a first die attached on the first die attach area;
a second die attached on a second die attach area of the lead frame;
a first bond wire electrically connecting the first die to a first end of the conductive trace; and
a second bond wire electrically connecting the second die to a second end of the conductive trace.

4. The semiconductor device of claim 1, wherein the insulated layer is glass, ceramic or polymer based material.

5. The semiconductor device of claim 1, wherein the conductive trace is a copper trace.

6. The semiconductor device of claim 1, further comprising a finishing layer plated on a top surface of the conductive trace for wire bonding.

7. The semiconductor device of claim 1, wherein the insulated layer has an L-shape, and the conductive trace is arranged along with the L-shape.

8. The semiconductor device of claim 1, wherein the insulated layer has a ring shape that allows a plurality of conductive traces arranged around a center of the ring shape.

9. The semiconductor device of claim 1, wherein the insulated layer is plated with a plurality of conductive traces, wherein each of the plurality of conductive traces has at least one contact element, wherein the contact elements of the plurality of conductive traces are arranged in a zigzag row.

10. A lead frame, comprising:
a flag having a first die attach area and an interposer area;
a plurality of leads surrounding the flag; and
an insulated layer plated with at least one conductive trace formed on the interposer area.

11. The lead frame of claim 10, wherein the insulated layer is glass, ceramic or polymer based material.

12. The lead frame of claim 10, further comprising a silver layer plated on an upper surface of the conductive trace.

13. The lead frame of claim 10, wherein the insulated layer has an L-shape, and the conductive trace is arranged along with the L-shape.

14. The lead frame of claim 10, wherein the insulated layer has a ring shape that allows a plurality of conductive traces arranged around a center of the ring shape.

15. The lead frame of claim 10, wherein the insulated layer is plated with a plurality of conductive traces, wherein each of the plurality of conductive traces has at least one contact element, wherein the contact elements of the plurality of conductive traces are arranged in a zigzag row.

16. A method for assembling a semiconductor device, the method comprising:
providing a lead frame having a flag and a plurality of leads surrounding the flag, wherein the flag includes a first die attach area and an interposer area;
forming an insulated layer on the interposer area; and
plating at least one conductive trace on the insulated layer.

17. The method of claim 16, further comprising:
attaching a first die on the first die attach area;
electrically connecting the first die to a first end of the conductive trace with a first bond wire; and
electrically connecting a second end of the conductive trace to a lead of the plurality of leads with a second bond wire.

18. The method of claim 16, further comprising:
attaching a first die on the first die attach area;
attaching a second die on a second die attach area of the flag;
electrically connecting the first die to a first end of the conductive trace with a first bond wire; and
electrically connecting the second die to a second end of the conductive trace with a second bond wire.

19. The method of claim 16, wherein the insulated layer is formed by a screen print or photo mask process.

20. The method of claim 16, further comprising plating a finishing layer on a top surface of the conductive trace for wire bonding.
